(19) United States
(12) Patent Application Publication
(10) Pub. No.: US 2017/0115360 A1
(43) Pub. Date: Apr. 27, 2017

(54) Magnetic Field Sensor With Integrated Self-Test Reset Wire

(71) Applicant: Memsic Semiconductor (Wuxi) Co., Ltd., Wuxi (CN)

(72) Inventors: Leyue Jiang, Wuxi (CN); Bin Li, Andover, MA (US)

(21) Appl. No.: 15/299,283

(22) Filed: Oct. 20, 2016

(30) Foreign Application Priority Data
Oct. 21, 2015 (CN) 201510686064.6

(51) Int. Cl. G01R 33/00; G01R 33/09

(52) U.S. Cl. CPC G01R 33/0023; G01R 33/09

(57) ABSTRACT

A magnetic field sensor with an integrated self-test reset wire is provided. The magnetic field sensor includes at least one sensing unit having a magnetic easy axis and a magneto-sensitive axis perpendicular to the magnetic easy axis, and at least one self-test reset wire disposed above or below the at least one sensing unit. A predetermined angle between the self-test reset wire and the magneto-sensitive axis of the corresponding sensing unit is greater than 0 degrees and less than 45 degrees. The self-test reset wire is configured to realize a set-reset function and a self-test function for the magnetic field sensor.

### CROSS-REFERENCE TO RELATED APPLICATION

The present disclosure claims the priority benefit of Chinese Patent Application No. 201510686064.6, filed on 21 Oct. 2015, which is incorporated by reference in its entirety.

### TECHNICAL FIELD

The present disclosure relates to a magnetic field sensor, and in particular, to a magnetic field sensor with an integrated self-test reset wire.

### BACKGROUND

Sensors based on magneto-resistance (MR) effects have been widely used. Typically, MR-based sensors include anisotropic magneto-resistance (AMR)-based sensors, giant magneto-resistance (GMR)-based sensors, and tunneling magneto-resistance (TMR)-based sensors.

In general, an electrical resistance of a MR-based sensor changes with a change of a magnetic field, such as a change in magnitude or direction thereof. A magnetic field sensor of this kind typically has a layer of soft magnetic material of iron, cobalt, nickel, or permalloy such as cobalt-iron-boron alloy or nickel-iron alloy. A change in magnitude or direction of a magnetic field would change a magnetization direction of the soft magnetic material, thereby changing a resistance thereof.

To achieve an accurate measurement of the magnetic field, the soft magnetic layer needs to be re-magnetized before the magnetic field sensor is used for the measurement. A common method for re-magnetizing the soft magnetic layer is passing a large current through a wire adjacent to a basic sensing unit of the magnetic field sensor. The large current would produce a strong magnetic field, and all magnetic domains of the basic sensing unit would be arranged to align with the magnetic easy axis. The magnetic easy axis depends on anisotropy of the basic sensing unit of the magnetic field sensor. Depending on the direction of the current in the wire, the magnetic domains may be arranged along one of the two opposite directions parallel with the magnetic easy axis. Generally, such an operation is called a function of “set” or “reset”. In addition to initializing the magnetization of the soft magnetic layer, the set-reset function may also help restoring the magnetization of the soft magnetic layer. That is, if the magnetic field sensor is disturbed momentarily by an external magnetic field which is rather strong, even after the disturbing magnetic field is removed, the magnetic domains of the soft magnetic layer may not be able to restore to their initial states. This could result in a subsequent measurement error. With the set-reset function, the magnetic domains of the soft magnetic layer can be restored.

With continuous declination of the manufacturing cost per magnetic field sensor chip, the production testing cost has been increasing in proportion for a magnetic field sensor. In addition to common equipment for testing electrical performances, production testing of magnetic field sensors also requires equipment for generating various magnetic fields. The equipment for generating magnetic fields, such as Helmholtz coils, may significantly increase the overall cost for magnetic field sensors.

It follows that the overall cost may be greatly lowered provided that the testing of a magnetic field sensor can be accomplished in-situ on the magnetic field sensor itself, without any equipment generating external magnetic fields. For example, a magnetic field sensor may be placed in a known magnetic field, and a reading of the magnetic field sensor may be compared to the known magnetic field to calibrate a sensitivity, error and/or other parameters of the magnetic field sensor. Such a known magnetic field may be generated by a wire adjacent to the magnetic field sensor.

Typically, the external magnetic field for testing a magnetic field sensor is placed parallel with the magneto-sensitive axis of the sensor and perpendicular to the magnetic easy axis of the sensor. Therefore, two separate sets of wires adjacent to the sensor are required to realize the set-reset function and the self-test function. This would require the production processes of the magnetic field sensor to include two metal layers, and the additional metal deposition and photolithography steps for the two metal layers would increase the production cost of the magnetic field sensor.

Therefore, there is a need for an improved scheme for realizing the set-reset function and the self-test function simultaneously in a MR-based magnetic field sensor.

### SUMMARY

This section is for the purpose of summarizing some aspects of the present disclosure and to briefly introduce some preferred embodiments. Simplifications or omissions in this section as well as in the abstract or the title of this description may be made to avoid obscuring the purpose of this section, the abstract and the title. Such simplifications or omissions are not intended to limit the scope of the present disclosure.

One object of the present disclosure is to provide an improved magnetic field sensor, which is able to realize a set-reset function and a self-test function based on a single wire.

According to one aspect of the present disclosure, the present disclosure provides a magnetic field sensor. The magnetic field sensor may include a sensing unit having a magnetic easy axis and a magneto-sensitive axis perpendicular to the magnetic easy axis. The magnetic field sensor may also include a self-test reset wire disposed adjacent to the sensing unit. A predetermined angle may be formed between an extending direction of the self-test reset wire and the magneto-sensitive axis of the sensing unit. The predetermined angle may be greater than 0 degrees and less than 45 degrees.

In an embodiment, the magnetic easy axis of the sensing unit is parallel with an x-axis, and the magneto-sensitive axis of the sensing unit is parallel with a y-axis which is perpendicular to the x-axis. Moreover, a current passing through the self-test reset wire may produce a magnetic field where the sensing unit is located. The magnetic field may have an x-component parallel with the x-axis and a y-component parallel with the y-axis.

In a further embodiment, the magnetic field sensor may have a set-reset mode and a self-test mode. When the magnetic field sensor operates in the set-reset mode, the current is a first current, the magnetic field is a first magnetic field, and the x-component of the first magnetic field may set or reset the sensing unit such that magnetic domains of the sensing unit are aligned with the magnetic easy axis. When the magnetic field sensor operates in the self-test mode, the current is a second current, the magnetic field is a second magnetic field, and the y-component of the second magnetic field may result in a change of a magneto-resistance of the sensing unit. The change in the magneto-resistance may subsequently result in a self-test of the magnetic field sensor. In some embodiments, the second current may be less than the first current.

One of the features, benefits and advantages in the present disclosure is to provide techniques for providing a single self-test reset wire forming a predetermined angle with the magneto-sensitive axis of the magnetic field sensor so as to realize the set-reset function and the self-test function via the single self-test reset wire.

Other objects, features, and advantages of the present disclosure will become apparent upon examining the following detailed description of an embodiment thereof, taken in conjunction with the attached drawings.

### BRIEF DESCRIPTION OF THE DRAWINGS

These and other features, aspects, and advantages of the present disclosure will become better understood with regard to the following description, appended claims, and accompanying drawings.

FIG. 1 shows a diagram of a magnetic field sensor in accordance with a first embodiment of the present disclosure.

FIG. 2 shows a diagram of a magnetic field sensor in accordance with a second embodiment of the present disclosure.

FIG. 3 shows a circuit diagram of a Wheatstone bridge of the magnetic field sensor in FIG. 2.

FIG. 4 shows a diagram of a magnetic field sensor in accordance with a third embodiment of the present disclosure.

### DETAILED DESCRIPTION OF THE PREFERRED EMBODIMENTS

The detailed description of the present disclosure is presented largely in terms of procedures, steps, logic blocks, processing, or other symbolic representations that directly or indirectly resemble the operations of devices or systems contemplated in the present disclosure. These descriptions and representations are typically used by those skilled in the art to most effectively convey the substance of their work to others skilled in the art.

Reference herein to “one embodiment” or “an embodiment” means that a particular feature, structure, or characteristic described in connection with the embodiment can be included in at least one embodiment of the present disclosure. The appearances of the phrase “in one embodiment” in various places in the specification are not necessarily all referring to the same embodiment, nor are separate or alternative embodiments mutually exclusive of other embodiments. Further, the order of blocks in process flowcharts or diagrams or the use of sequence numbers representing one or more embodiments of the present disclosure do not inherently indicate any particular order nor imply any limitations in the present disclosure.

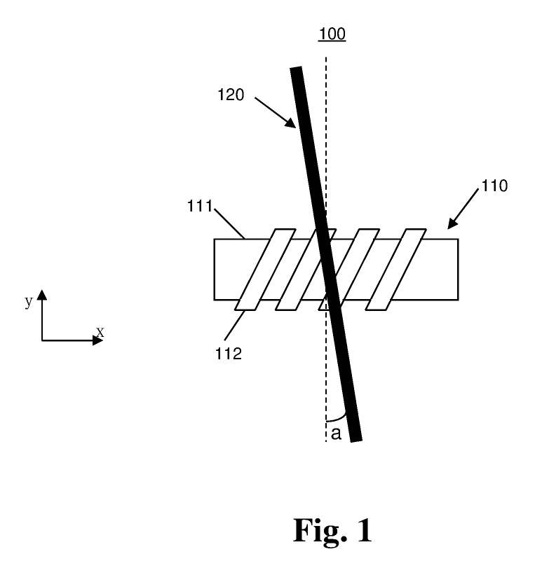

FIG. 1 shows a diagram of a magnetic field sensor 100 according to a first embodiment of the present disclosure. As shown in FIG. 1, the magnetic field sensor 100 includes a sensing unit 110, a self-test reset wire 120 and an insulating layer (now shown) between the sensing unit 110 and the self-test reset wire 120. The self-test reset wire 120 corresponds to the sensing unit 110 and is disposed above or below the sensing unit 110.

The sensing unit 110 has a magnetic easy axis, as well as a magneto-sensitive axis that is perpendicular to the magnetic easy axis. For the convenience of description, an x-axis and a y-axis perpendicular to the x-axis are defined in FIG. 1. Specifically, the x-axis is defined to be parallel with the magnetic easy axis of the sensing unit 110, and the y-axis is defined to be parallel with the magneto-sensitive axis of the sensing unit 110. The sensing unit 110 may be an AMR-based sensing unit, a GMR-based sensing unit, or a TMR-based sensing unit.

In one embodiment, the sensing unit 110 may include a longitudinal magneto-resistive bar 111 extending along the magnetic easy axis. The sensing unit 110 may also include a plurality of electrically conductive stripes 112 that are parallel with each other. Each conductive stripe 112 may be disposed on the magneto-resistive bar 111 and form a predetermined angle with the magneto-resistive bar 111. The magneto-resistive bar 111 may be made of a soft magnetic material such as iron, cobalt, nickel, cobalt-iron-boron alloy or nickel-iron alloy. A layer where the magneto-resistive bar 111 is located is also called a soft magnetic layer or a magneto-resistive layer. The conductive stripes 112 may be made of an electrically conductive material such as titanium (Ti), copper (Cu), and the like.

The self-test reset wire 120 may be located above or below the sensing unit 110, and a predetermined angle may be formed between an extending direction of the self-test reset wire 120 and the magneto-sensitive axis of the sensing unit 110. The predetermined angle may be greater than 0 degrees and less than 45 degrees. Preferably, the predetermined angle may be greater than 4 degrees and less than 15 degrees. The self-test reset wire 120 may be made of an electrically conductive material, and the conductive material may be, but not limited to, a conductive metal, such as copper or aluminum. It is to be understood that the self-test reset wire 120 may include one wire or a plurality of parallel wires. However, the directions of currents flowing in the plurality of wires of the same self-test reset wire 120 are identical.

The predetermined angle between the self-test reset wire 120 and the magneto-sensitive axis of the sensing unit 110 may place the self-test reset wire 120 in an orientation that is neither perpendicular to, nor parallel with, the sensing unit 110. When a current passes through the self-test reset wire 120, the current may produce a magnetic field having an x-component (i.e., a component parallel with the x-axis) and a y-component (i.e., a component parallel with the y-axis) in a plane where the corresponding sensing unit 110 is located.

The magnetic field sensor 100 may operate in a set-reset mode and a self-test mode.

When the magnetic field sensor 100 operates in the set-reset mode, a first current 11 may pass through the self-test reset wire 120, and a first magnetic field may thus be produced in the plane where the corresponding sensing unit 110 is located. The x-component of the first magnetic field may set or reset the corresponding sensing unit 110 such that magnetic domains of the corresponding sensing unit 110 are aligned with, or return to, the magnetic easy axis. The first current 11 is strong enough to generate the first magnetic field with a sufficiently large x-component for setting or resetting the magnetization direction of the sensing unit 110.

When the magnetic field sensor 100 operates in the self-test mode, a second current 12, of a known or predetermined value, may pass through the self-test reset wire 120, and a second magnetic field, also of a known or predetermined value, may thus be produced in the plane where the corresponding sensing unit 110 is located. The y-component of the second magnetic field may result in a known change of a magneto-resistance of the corresponding sensing unit 110, and the known change of the magneto-resistance may be subsequently detected to achieve a self-test of the corresponding sensing unit. The second current 12 may be less than the first current 11, as long as it is able to create enough y-component that is sensible to the sensing unit 110.

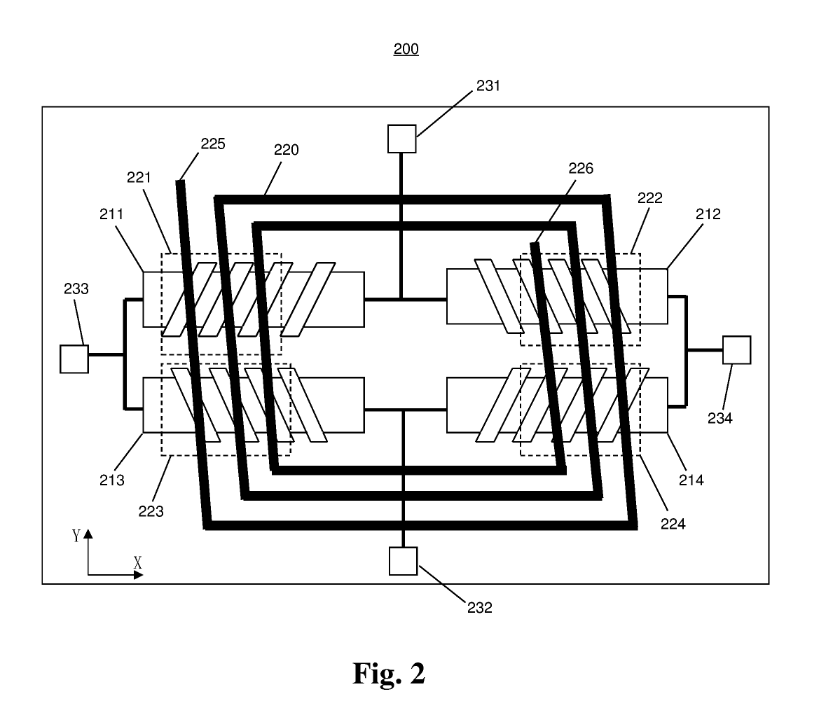

FIG. 2 shows a diagram of a magnetic field sensor 200 according to a second embodiment of the present disclosure. As shown in FIG. 2, the magnetic field sensor 200 includes a first power supply terminal 231, a second power supply terminal 232, a first output terminal 233, a second output terminal 234, four sensing units, a self-test reset coil 220 and an insulating layer (not shown) between the sensing units and the self-test reset coil 220. The self-test reset coil 220 is located above or below the sensing units.

The four sensing units are respectively denoted as a first sensing unit 211, a second sensing unit 212, a third sensing unit 213 and a fourth sensing unit 214. The self-test reset coil 220 includes at least four self-test reset wires, respectively denoted as a first self-test reset wire (i.e., the portion of the self-test reset coil 220 within dashed box 221), a second self-test reset wire (i.e., the portion of the self-test reset coil 220 within dashed box 222), a third self-test reset wire (i.e., the portion of the self-test reset coil 220 within dashed box 223), and a fourth self-test reset wire (i.e., the portion of the self-test reset coil 220 within dashed box 224). The four self-test reset wires are connected to each other to form the self-test reset coil 220. Moreover, the self-test reset coil 220 has a first terminal 225 and a second terminal 226.

In the embodiment shown in FIG. 2, each of the self-test reset wires includes three wire units in parallel. Nevertheless, in other embodiments, each of the self-test reset wires in FIG. 2 may include one, two or more wire units in parallel. The directions of currents flowing in the wire units of every individual self-test reset wire need to be identical.

In terms of position and functional effect, the first self-test reset wire 221, the second self-test reset wire 222, the third self-test reset wire 223 and the fourth self-test reset wire 224 correspond to the first sensing unit 211, the second sensing unit 212, the third sensing unit 213 and the fourth sensing unit 214, respectively.

Furthermore, the first power supply terminal 231 is coupled to a first end of the first sensing unit 211 and a first end of the second sensing unit 212; the second power supply terminal 232 is coupled to a second end of the third sensing unit 213 and a second end of the fourth sensing unit 214; the first output terminal 233 is coupled to a second end of the first sensing unit 211 and a first end of the third sensing unit 213; and the second output terminal 234 is coupled to a second end of the second sensing unit 212 and a first end of the fourth sensing unit 214.

It follows that a current flowing in the first self-test reset wire 221 corresponding to the first sensing unit 211 flows in a same direction as a current flowing in the third self-test reset wire 223 corresponding to the third sensing unit 213. Likewise, a current flowing in the second self-test reset wire 222 corresponding to the second sensing unit 212 flows in a same direction as a current flowing in the fourth self-test reset wire 224 corresponding to the fourth sensing unit 214. In addition, a flow direction of the currents flowing in the self-test reset wires 221 and 223 respectively corresponding to the first sensing unit 211 and the third sensing unit 213 is opposite to a flow direction of the currents flowing in the self-test reset wires 222 and 224 respectively corresponding to the second sensing unit 212 and the fourth sensing unit 214.

Each sensing unit of magnetic field sensor 200 has a magnetic easy axis and a magneto-sensitive axis perpendicular to the magnetic easy axis. Similar to magnetic field sensor 100 of FIG. 1, an x-axis and a y-axis perpendicular to the x-axis may be defined, with the magnetic easy axes of the sensing units parallel with the x-axis, and the magneto-sensitive axes of the sensing units parallel with the y-axis. The type, structure, working principle and manufacturing process of each sensing unit in FIG. 2 may be referred to the sensor unit in FIG. 1, and will not be repeated here.

In FIG. 2, a predetermined angle b (not shown) may be formed between an extending direction of each self-test reset wire and the magneto-sensitive axis of the corresponding sensing unit, such that the self-test reset wire and the corresponding sensing unit are neither perpendicular to nor parallel with one another. The predetermined angle b may be greater than 0 degrees and less than 45 degrees. Preferably, the predetermined angle may be greater than 4 degrees and less than 15 degrees. When a current passes through the self-test reset coil 220, the current may produce a magnetic field having an x-component (i.e., a component parallel with the x-axis) and a y-component (i.e., a component parallel with the y-axis) in a plane where corresponding sensing units 211, 212, 213 and 214 are located.

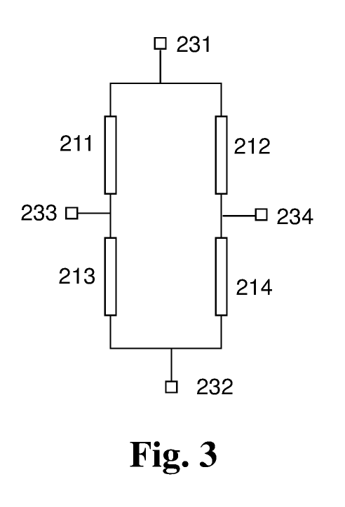

The sensing units in FIG. 2 constitute a Wheatstone bridge structure. FIG. 3 shows a circuit diagram of the Wheatstone bridge structure in FIG. 2. The first power supply terminal 231 may be a power supply voltage terminal, and the second power supply terminal 232 may be a ground terminal.

The magnetic field sensor 200 may operate in a set-reset mode and a self-test mode.

When the magnetic field sensor 200 operates in the set-reset mode, a first current may flow from the first terminal 225 to the second terminal 226. A first magnetic field may thus be produced in a plane where the sensing units 211, 212, 213 and 214 are located. The x-component of the first magnetic field may set or reset the sensing unit 211, 212, 213 and 214 such that the magnetic domains of each of the sensing units 211, 212, 213 and 214 are aligned with, or return to, the magnetic easy axis. The first current 11 is strong enough to generate the first magnetic field with a sufficiently large x-component for setting or resetting the magnetization direction of each of the sensing units 211, 212, 213 and 214.

When the magnetic field sensor 200 operates in the self-test mode, a second current 12, of a known or predetermined value, may flow from the first terminal 225 to the second terminal 226. A second magnetic field, also of a known or predetermined value, may thus be produced in the plane where the sensing units 211, 212, 213 and 214 are located. The y-component of the second magnetic field may result in a known change of a magneto-resistance of each of the sensing units 211, 212, 213 and 214. The known change of the magneto-resistances may lead to a change of a voltage across the first output terminal 233 and the second output terminal 234, and a self-test of the magnetic field sensor 200 may thus be achieved by detecting the change of the voltage across the first output terminal 233 and the second output terminal 234. The second current 12 may be less than the first current 11.

Accordingly, the set-reset function and the self-test function may be realized simultaneously by a single self-test reset coil 220.

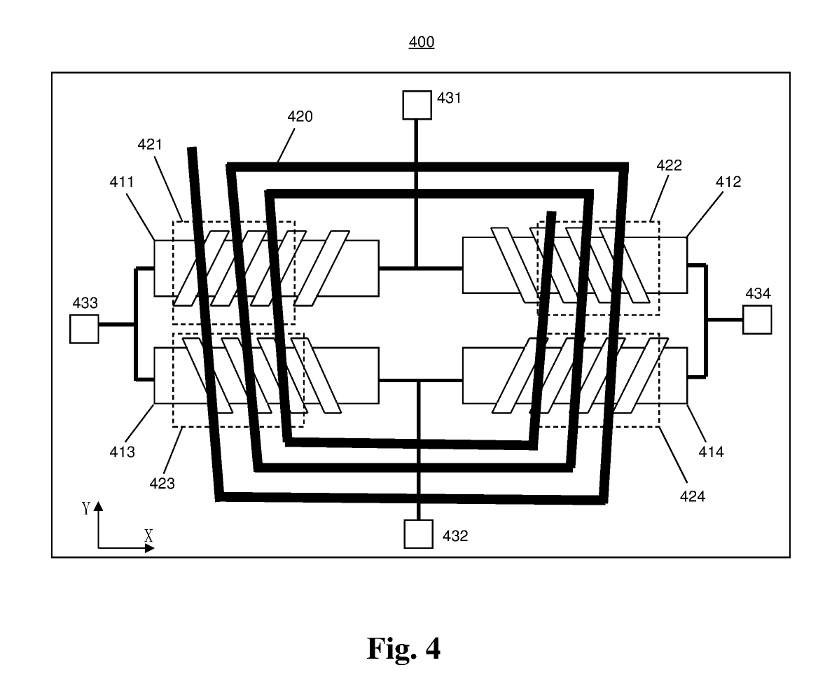

FIG. 4 shows a diagram of a magnetic field sensor 400 according to a third embodiment of the present disclosure. The magnetic field sensor 400 in FIG. 4 is basically same as the magnetic field sensor 200 in FIG. 2. The magnetic field sensor 400 likewise includes a first power supply terminal 431, a second power supply terminal 432, a first output terminal 433, a second output terminal 434, a first sensing unit 411, a second sensing unit 412, a third sensing unit 413, a fourth sensing unit 414, and a self-test reset coil 420. The self-test reset coil 420 likewise includes a first self-test reset wire (i.e., the portion of the self-test reset coil 420 within dashed box 421), a second self-test reset wire (i.e., the portion of the self-test reset coil 420 within dashed box 422), a third self-test reset wire (i.e., the portion of the self-test reset coil 420 within dashed box 423), and a fourth self-test reset wire (i.e., the portion of the self-test reset coil 420 within dashed box 424).

The difference between the magnetic field sensor 400 of FIG. 4 and the magnetic field sensor 200 of FIG. 2 lies in that, an inclination direction of the first self-test reset wire 421 and the third self-test reset wire 423 is different from that of the second self-test reset wire 422 and the fourth self-test reset wire 424.

An extending direction of each self-test reset wire may be at a predetermined angle with the magneto-sensitive axis of the corresponding sensing unit, such that the self-test reset wire and the corresponding sensing unit are neither perpendicular to nor parallel with one another. Preferably, the predetermined angle may be greater than 4 degrees and less than 15 degrees. When a current passes through the self-test reset coil 420, the current may produce a magnetic field having an x-component (i.e., a component parallel with the x-axis) and a y-component (i.e., a component parallel with the y-axis) in a plane where corresponding sensing units 411, 412, 413 and 414 are located. Accordingly, the set-reset function and the self-test function may be realized simultaneously by a single self-test reset coil 420.

The present disclosure has been described in sufficient details with a certain degree of particularity. It is understood to those skilled in the art that the present disclosure of embodiments has been made by way of examples only and that numerous changes in the arrangement and combination of parts may be resorted without departing from the spirit and scope of the present disclosure as claimed. Accordingly, the scope of the present disclosure is defined by the appended claims rather than the foregoing description of embodiments.

What is claimed is:

1. A magnetic field sensor, comprising:
at least one sensing unit having a magnetic easy axis and a magneto-sensitive axis perpendicular to the magnetic easy axis; and
at least one self-test reset wire disposed adjacent to the at least one sensing unit,
wherein a predetermined angle is formed between an extending direction of the at least one self-test reset wire and the magneto-sensitive axis of the at least one sensing unit, and wherein the predetermined angle is greater than 0 degrees and less than 45 degrees.

2. The magnetic field sensor according to claim 1, wherein the predetermined angle is greater than 4 degrees and less than 15 degrees.

3. The magnetic field sensor according to claim 1, wherein:
the magnetic easy axis of the at least one sensing unit is parallel with an x-axis,
the magneto-sensitive axis of the at least one sensing unit is parallel with a y-axis which is perpendicular to the x-axis, and
a current passing through the at least one self-test reset wire produces a magnetic field in a plane where the at least one sensing unit is located, the magnetic field having an x-component parallel with the x-axis and a y-component parallel with the y-axis.

4. The magnetic field sensor according to claim 3, wherein:
the magnetic field sensor has a set-reset mode and a self-test mode,
when the magnetic field sensor is in the set-reset mode, the current is a first current, the magnetic field is a first magnetic field, and the x-component of the first magnetic field sets or resets the at least one sensing unit such that magnetic domains of the at least one sensing unit are aligned with the magnetic easy axis,
when the magnetic field sensor is in the self-test mode, the current is a second current, the magnetic field is a second magnetic field, the y-component of the second magnetic field results in a change of a magneto-resistance of the at least one sensing unit, and the change in the magneto-resistance results in a self-test of the magnetic field sensor, and
the second current is less than the first current.

5. The magnetic field sensor according to claim 1, wherein:
the at least one sensing unit comprises a plurality of sensing units each having a respective magnetic easy axis, the respective magnetic easy axes of the plurality of sensing units parallel with each other, and
the at least one self-test reset wire comprises a plurality of self-test reset wires each corresponding to a respective one of the plurality of sensing units.

6. The magnetic field sensor according to claim 5, further comprising:
a first power supply terminal;
a second power supply terminal;
a first output terminal; and
a second output terminal,
wherein:
the plurality of sensing units comprises four sensing units respectively denoted as a first sensing unit, a second sensing unit, a third sensing unit and a fourth sensing unit,
the first power supply terminal is coupled to a first end of the first sensing unit and a first end of the second sensing unit,
the second power supply terminal is coupled to a second end of the third sensing unit and a second end of the fourth sensing unit,
the first output terminal is coupled to a second end of the first sensing unit and a first end of the third sensing unit,
the second output terminal is coupled to a second end of the second sensing unit and a first end of the fourth sensing unit,
a current flowing in the self-test reset wire corresponding to the first sensing unit and a current flowing in the self-test reset wire corresponding to the third sensing unit flow in a same direction denoted as a first flowing direction, and
a current flowing in the self-test reset wire corresponding to the second sensing unit and a current flowing in the self-test reset wire corresponding to the fourth sensing unit flow in a same direction denoted as a second flowing direction, the second flowing direction opposite to the first flowing direction.

7. The magnetic field sensor according to claim 5, wherein the plurality of self-test reset wires are connected with each other to form a self-test reset coil having a first terminal and a second terminal.

8. The magnetic field sensor according to claim 1, wherein the at least one sensing unit comprises an anisotropic magneto-resistance-based sensing unit, a giant magneto-resistance-based sensing unit, or a tunneling magneto-resistance-based sensing unit.

9. The magnetic field sensor according to claim 1, further comprising:
an insulating layer disposed between the at least one sensing unit and the at least one self-test reset wire.

10. The magnetic field sensor according to claim 1, wherein the at least one sensing unit comprises a longitudinal magneto-resistive bar and a plurality of conductive stripes disposed on the magneto-resistive bar, the longitudinal magneto-resistive bar extending along the magnetic easy axis, the plurality of conductive stripes parallel with each other and forming a predetermined angle with the longitudinal magneto-resistive bar.

11. The magnetic field sensor according to claim 10, wherein the magneto-resistive bar comprises iron, cobalt, nickel, cobalt-iron-boron alloy or nickel-iron alloy.
